(19) United States
(12) Patent Application Publication
(10) Pub. No.: US 2022/0137856 A1
(43) Pub. Date: May 5, 2022

(54) PROGRAM OPERATION EXECUTION DURING PROGRAM OPERATION SUSPEND

(71) Applicant: Micron Technology, Inc., Boise, ID (US)

(72) Inventor: Umberto Siciliani, Rubano (IT)

(21) Appl. No.: 16/949,452

(22) Filed: Oct. 29, 2020

(51) Int. Cl. G06F 3/06

(52) U.S. Cl. CPC G06F 3/0655; G06F 3/0679; G06F 3/0604

(57) ABSTRACT

A memory device includes a memory array and control logic, operatively coupled with the memory array. The control logic receives, from a requestor, a first request to perform a first memory access operation on the memory array and initiates the first memory access operation on the memory array. Prior to completion of the first memory access operation, the control logic receives, from the requestor, a second request to suspend performance of the first memory access operation and causes the memory device to enter a suspend state, wherein the first memory access operation is suspended during the suspend state. The control logic further receives, from the requestor, a third request to perform a dynamic single-level cell (SLC) program operation on the memory array while the memory device is in the suspend state and initiates the dynamic SLC program operation on the memory array.

### TECHNICAL FIELD

Embodiments of the disclosure relate generally to memory sub-systems, and more specifically, relate to a program operation execution during program operation suspend in a memory sub-system.

### BACKGROUND

A memory sub-system can include one or more memory devices that store data. The memory devices can be, for example, non-volatile memory devices and volatile memory devices. In general, a host system can utilize a memory sub-system to store data at the memory devices and to retrieve data from the memory devices.

### BRIEF DESCRIPTION OF THE DRAWINGS

The present disclosure will be understood more fully from the detailed description given below and from the accompanying drawings of various embodiments of the disclosure.

FIG. 1 illustrates an example computing system that includes a memory sub-system in accordance with some embodiments of the present disclosure.

FIG. 2 is a block diagram illustrating a memory sub-system implementing program operation execution during program operation suspend in accordance with some embodiments of the present disclosure.

FIG. 3 is a flow diagram of an example controller method of program operation execution during program operation suspend in accordance with some embodiments of the present disclosure.

FIG. 4 is a flow diagram of an example memory device method of program operation execution during program operation suspend in accordance with some embodiments of the present disclosure.

FIG. 5 is a block diagram illustrating operation of a command state machine for program operation execution during program operation suspend in a memory sub-system in accordance with some embodiments of the present disclosure.

FIG. 6 is a block diagram of an example computer system in which embodiments of the present disclosure can operate.

### DETAILED DESCRIPTION

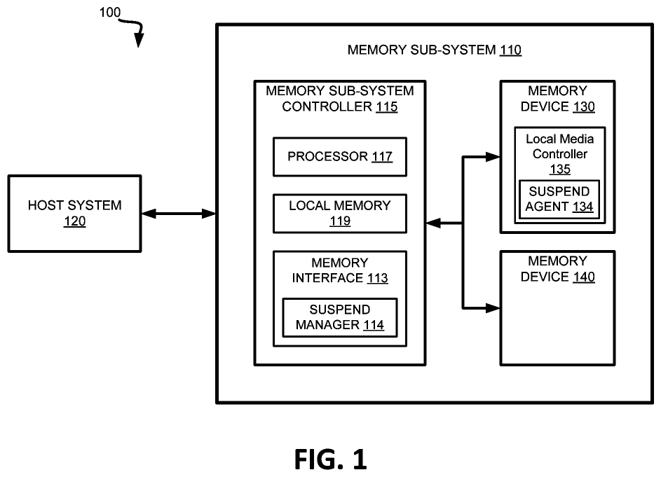

Aspects of the present disclosure are directed to program operation execution during program operation suspend in a memory sub-system. A memory sub-system can be a storage device, a memory module, or a hybrid of a storage device and memory module. Examples of storage devices and memory modules are described below in conjunction with FIG. 1. In general, a host system can utilize a memory sub-system that includes one or more components, such as memory devices that store data. The host system can provide data to be stored at the memory sub-system and can request data to be retrieved from the memory sub-system.

A memory sub-system can include high density non-volatile memory devices where retention of data is desired when no power is supplied to the memory device. One example of non-volatile memory devices is a negative-and (NAND) memory device. Other examples of non-volatile memory devices are described below in conjunction with FIG. 1. A non-volatile memory device is a package of one or more dies. Each die can consist of one or more planes. For some types of non-volatile memory devices (e.g., NAND devices), each plane consists of a set of physical blocks. Each block consists of a set of pages. Each page consists of a set of memory cells (“cells”). A cell is an electronic circuit that stores information. Depending on the cell type, a cell can store one or more bits of binary information, and has various logic states that correlate to the number of bits being stored. The logic states can be represented by binary values, such as “0” and “1”, or combinations of such values.

A memory device can be made up of bits arranged in a two-dimensional or a three-dimensional grid. Memory cells are etched onto a silicon wafer in an array of columns (also hereinafter referred to as bitlines) and rows (also hereinafter referred to as wordlines). A wordline can refer to one or more rows of memory cells of a memory device that are used with one or more bitlines to generate the address of each of the memory cells. The intersection of a bitline and wordline constitutes the address of the memory cell. A block hereinafter refers to a unit of the memory device used to store data and can include a group of memory cells, a wordline group, a wordline, or individual memory cells. One or more blocks can be grouped together to form a plane of the memory device in order to allow concurrent operations to take place on each plane. The memory device can include circuitry that performs concurrent memory page accesses of two or more memory planes. For example, the memory device can include multiple access line driver circuits and power circuits that can be shared by the planes of the memory device to facilitate concurrent access of pages of two or more memory planes, including different page types. For ease of description, these circuits can be generally referred to as independent plane driver circuits. Depending on the storage architecture employed, data can be stored across the memory planes (i.e. in stripes). Accordingly, one request to read a segment of data (e.g., corresponding to one or more data addresses), can result in read operations performed on two or more of the memory planes of the memory device.

In certain memory sub-systems it is quite common to receive a request to perform a memory access operation, such as a program operation of data from a host system, and then to subsequently receive a request to perform another memory access operation, such as a read operation on that same data from the host system right away, possibly even before the program operation has been completed. Conventional memory sub-systems sometimes keep the data being programmed in controller memory (e.g., dynamic random access memory (DRAM)) while the underlying memory device (e.g., negative-and (NAND) type flash memory) of the memory sub-system is being programmed, and then flush the controller memory when the program operation is complete. As long as the programming time (i.e., the time associated with performing the program operation of the memory device) is relatively short, a controller memory of reasonable size can accommodate the program data. When the memory device uses certain types of memory cells, such as triple level cells (TLCs) or quad-level cells (QLCs), however, the programming times can increase significantly. As such, the command latency time associated with the subsequently received memory access commands is increased significantly. If a subsequent request to perform a read operation is received while the program operation is still ongoing, certain memory sub-systems must wait until the program operation is complete before performing the read operation on the memory device. This can lead to significant latency in responding to requests from the host system.

In order to reduce latency in mixed workloads (e.g., a combination of program operations and read operations, such as a program operation followed immediately by a read operation), certain memory sub-systems utilize a program suspend protocol to allow subsequently received memory access commands (e.g., read operations) to access a page of a memory device on which a program operation is currently being performed. The program suspend protocol can use the memory device to temporarily pause the program operation to allow access to the memory array. In particular, when the memory sub-system receives a request to perform a memory access operation on data stored in a page of the memory device while a program operation (e.g., a TLC program operation) is in progress, a suspend manager of the memory sub-system controller can issue a specific program suspend command which causes the memory device to enter a suspend state. Certain memory devices, and their associated suspend protocols, only permit a limited number of types of commands (e.g., single plane or multi-plane read operations), to be performed while the memory device is in the suspend state. Some memory devices, however, support a different type of program operation, such as a dynamic single-level cell (SLC) program operation which requires low memory endurance and has a significantly shorter program time than a TLC program operation, for example. Many suspend protocols, however, do not permit a dynamic SLC program operation to be performed when the memory device is in the suspend state. Accordingly, despite having a shorter program time, a dynamic SLC program operation must wait to be performed until any pending memory access operations are complete. This causes increased latency in responding to requests from the host system and negatively impacts a quality of service provided by the memory sub-system.

Aspects of the present disclosure address the above and other deficiencies by permitting program operation execution during program operation suspend in a memory sub-system. In one embodiment, control logic of a memory device receives, from a requestor, such as the memory sub-system controller or host system, a first request to perform a first memory access operation on a memory array of the memory device and initiates the first memory access operation on the memory array. In one embodiment, the first memory access operation is a multi-level cell (MLC) program operation, such as a TLC program operation or a QLC program operation. Prior to completion of the first memory access operation, the control logic receives, from the requestor, a second request to suspend performance of the first memory access operation and causes the memory device to enter a suspend state, wherein the first memory access operation is suspended during the suspend state. The control logic further receives, from the requestor, a third request to perform a dynamic single-level cell (SLC) program operation on the memory array while the memory device is in the suspend state and initiates the dynamic SLC program operation on the memory array. The first memory access operation can subsequently be resumed upon completion of the dynamic SLC program operation.

Advantages of this approach include, but are not limited to, improved performance in the memory sub-system. In the manner described herein, the latency associated with completion of subsequently received memory access commands (e.g., dynamic SLC program) with lower operation times (e.g., program times) can be reduced as performance of those operations need not wait for completion of ongoing memory access operations (e.g., MLC program operations) with higher operation times. Accordingly, the overall quality of service level of the memory sub-system is improved as a minimum level of performance for processing memory access operations can be maintained.

FIG. 1 illustrates an example computing system 100 that includes a memory sub-system 110 in accordance with some embodiments of the present disclosure. The memory sub-system 110 can include media, such as one or more volatile memory devices (e.g., memory device 140), one or more non-volatile memory devices (e.g., memory device 130), or a combination of such.

A memory sub-system 110 can be a storage device, a memory module, or a hybrid of a storage device and memory module. Examples of a storage device include a solid-state drive (SSD), a flash drive, a universal serial bus (USB) flash drive, an embedded Multi-Media Controller (eMMC) drive, a Universal Flash Storage (UFS) drive, a secure digital (SD) and a hard disk drive (HDD). Examples of memory modules include a dual in-line memory module (DIMM), a small outline DIMM (SO-DIMM), and various types of non-volatile dual in-line memory module (NVDIMM).

The computing system 100 can be a computing device such as a desktop computer, laptop computer, network server, mobile device, a vehicle (e.g., airplane, drone, train, automobile, or other conveyance), Internet of Things (IoT) enabled device, embedded computer (e.g., one included in a vehicle, industrial equipment, or a networked commercial device), or such computing device that includes memory and a processing device.

The computing system 100 can include a host system 120 that is coupled to one or more memory sub-systems 110. In some embodiments, the host system 120 is coupled to different types of memory sub-system 110. FIG. 1 illustrates one example of a host system 120 coupled to one memory sub-system 110. As used herein, “coupled to” or “coupled with” generally refers to a connection between components, which can be an indirect communicative connection or direct communicative connection (e.g., without intervening components), whether wired or wireless, including connections such as electrical, optical, magnetic, etc.

The host system 120 can include a processor chipset and a software stack executed by the processor chipset. The processor chipset can include one or more cores, one or more caches, a memory controller (e.g., NVDIMM controller), and a storage protocol controller (e.g., PCIe controller, SATA controller). The host system 120 uses the memory sub-system 110, for example, to write data to the memory sub-system 110 and read data from the memory sub-system 110.

The host system 120 can be coupled to the memory sub-system 110 via a physical host interface. Examples of a physical host interface include, but are not limited to, a serial advanced technology attachment (SATA) interface, a peripheral component interconnect express (PCIe) interface, universal serial bus (USB) interface, Fibre Channel, Serial Attached SCSI (SAS), a double data rate (DDR) memory bus, Small Computer System Interface (SCSI), a dual in-line memory module (DIMM) interface (e.g., DIMM socket interface that supports Double Data Rate (DDR)), etc. The physical host interface can be used to transmit data between the host system 120 and the memory sub-system 110. The host system 120 can further utilize an NVM Express (NVMe) interface to access components (e.g., memory devices 130) when the memory sub-system 110 is coupled with the host system 120 by the physical host interface (e.g., PCIe bus). The physical host interface can provide an interface for passing control, address, data, and other signals between the memory sub-system 110 and the host system 120. FIG. 1 illustrates a memory sub-system 110 as an example. In general, the host system 120 can access multiple memory sub-systems via a same communication connection, multiple separate communication connections, and/or a combination of communication connections.

The memory devices 130,140 can include any combination of the different types of non-volatile memory devices and/or volatile memory devices. The volatile memory devices (e.g., memory device 140) can be, but are not limited to, random access memory (RAM), such as dynamic random access memory (DRAM) and synchronous dynamic random access memory (SDRAM).

Some examples of non-volatile memory devices (e.g., memory device 130) include negative-and (NAND) type flash memory and write-in-place memory, such as a three-dimensional cross-point (“3D cross-point”) memory device, which is a cross-point array of non-volatile memory cells. A cross-point array of non-volatile memory can perform bit storage based on a change of bulk resistance, in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased. NAND type flash memory includes, for example, two-dimensional NAND (2D NAND) and three-dimensional NAND (3D NAND).

Each of the memory devices 130 can include one or more arrays of memory cells. One type of memory cell, for example, single level cells (SLC) can store one bit per cell. Other types of memory cells, such as multi-level cells (MLCs), triple level cells (TLCs), quad-level cells (QLCs), and penta-level cells (PLCs) can store multiple bits per cell. In some embodiments, each of the memory devices 130 can include one or more arrays of memory cells such as SLCs, MLCs, TLCs, QLCs, or any combination of such. In some embodiments, a particular memory device can include an SLC portion, and an MLC portion, a TLC portion, a QLC portion, or a PLC portion of memory cells. The memory cells of the memory devices 130 can be grouped as pages that can refer to a logical unit of the memory device used to store data. With some types of memory (e.g., NAND), pages can be grouped to form blocks.

Although non-volatile memory components such as 3D cross-point array of non-volatile memory cells and NAND type flash memory (e.g., 2D NAND, 3D NAND) are described, the memory device 130 can be based on any other type of non-volatile memory, such as read-only memory (ROM), phase change memory (PCM), self-selecting memory, other chalcogenide based memories, ferroelectric transistor random-access memory (FeTRAM), ferroelectric random access memory (FeRAM), magneto random access memory (MRAM), Spin Transfer Torque (STT)-MRAM, conductive bridging RAM (CBRAM), resistive random access memory (RRAM), oxide based RRAM (OxRAM), negative-or (NOR) flash memory, and electrically erasable programmable read-only memory (EEPROM).

A memory sub-system controller 115 (or controller 115 for simplicity) can communicate with the memory devices 130 to perform operations such as reading data, writing data, or erasing data at the memory devices 130 and other such operations. The memory sub-system controller 115 can include hardware such as one or more integrated circuits and/or discrete components, a buffer memory, or a combination thereof. The hardware can include a digital circuitry with dedicated (i.e., hard-coded) logic to perform the operations described herein. The memory sub-system controller 115 can be a microcontroller, special purpose logic circuitry (e.g., a field programmable gate array (FPGA), an application specific integrated circuit (ASIC), etc.), or other suitable processor.

The memory sub-system controller 115 can be a processing device, which includes one or more processors (e.g., processor 117), configured to execute instructions stored in a local memory 119. In the illustrated example, the local memory 119 of the memory sub-system controller 115 includes an embedded memory configured to store instructions for performing various processes, operations, logic flows, and routines that control operation of the memory sub-system 110, including handling communications between the memory sub-system 110 and the host system 120.

In some embodiments, the local memory 119 can include memory registers storing memory pointers, fetched data, etc. The local memory 119 can also include read-only memory (ROM) for storing micro-code. While the example memory sub-system 110 in FIG. 1 has been illustrated as including the memory sub-system controller 115, in another embodiment of the present disclosure, a memory sub-system 110 does not include a memory sub-system controller 115, and can instead rely upon external control (e.g., provided by an external host, or by a processor or controller separate from the memory sub-system).

In general, the memory sub-system controller 115 can receive commands or operations from the host system 120 and can convert the commands or operations into instructions or appropriate commands to achieve the desired access to the memory devices 130. The memory sub-system controller 115 can be responsible for other operations such as wear leveling operations, garbage collection operations, error detection and error-correcting code (ECC) operations, encryption operations, caching operations, and address translations between a logical address (e.g., logical block address (LBA), namespace) and a physical address (e.g., physical block address) that are associated with the memory devices 130. The memory sub-system controller 115 can further include host interface circuitry to communicate with the host system 120 via the physical host interface. The host interface circuitry can convert the commands received from the host system into command instructions to access the memory devices 130 as well as convert responses associated with the memory devices 130 into information for the host system 120.

The memory sub-system 110 can also include additional circuitry or components that are not illustrated. In some embodiments, the memory sub-system 110 can include a cache or buffer (e.g., DRAM) and address circuitry (e.g., a row decoder and a column decoder) that can receive an address from the memory sub-system controller 115 and decode the address to access the memory devices 130.

In some embodiments, the memory devices 130 include local media controllers 135 that operate in conjunction with memory sub-system controller 115 to execute operations on one or more memory cells of the memory devices 130. An external controller (e.g., memory sub-system controller 115) can externally manage the memory device 130 (e.g., perform media management operations on the memory device 130). In some embodiments, memory sub-system 110 is a managed memory device, which includes a raw memory device 130 having control logic (e.g., local media controller 135) on the die and a controller (e.g., memory sub-system controller 115) for media management within the same memory device package. An example of a managed memory device is a managed NAND (MNAND) device.

In one embodiment, the memory sub-system 110 includes a memory interface component 113, which includes suspend manager 114. Memory interface component 113 is responsible for handling interactions of memory sub-system controller 115 with the memory devices of memory sub-system 110, such as memory device 130. For example, memory interface component 113 can send memory access commands corresponding to requests received from host system 120 to memory device 130, such as program commands, read commands, or other commands. In addition, memory interface component 113 can receive data from memory device 130, such as data retrieved in response to a read command or a confirmation that a program command was successfully performed. In some embodiments, the memory sub-system controller 115 includes at least a portion of the suspend manager 114. For example, the memory sub-system controller 115 can include a processor 117 (processing device) configured to execute instructions stored in local memory 119 for performing the operations described herein. In some embodiments, the memory interface component 113 is part of the host system 110, an application, or an operating system. In one embodiment, memory interface 113 includes suspend manager 114, among other sub-components. Suspend manager 114 can direct specific commands, including suspend and resume commands, to memory device 130 to manage collisions between different memory access operations. A collision can occur when a first memory access operation is being performed on cells of a certain data block, sub-block, and wordline of memory device 130 when a request to perform a second memory access operation on cells of the same data block, sub-block and wordline is received. In response to such a collision, suspend manager 114 can determine how to proceed. In one embodiment, suspend manager 114 can suspend the first memory access operation by issuing a designated suspend command to memory device 130 and then issuing a request to perform a second memory access operation while the first memory access operation is suspended. In one embodiment, the second memory access operation can include a dynamic SLC program operation which has a substantially lower program time than a MLC program operation. Further details with regards to the operations of suspend manager 114 are described below.

In one embodiment, memory device 130 includes a suspend agent 134 configured to carry out corresponding memory access operations, in response to receiving the memory access commands from suspend manager 114. In some embodiments, local media controller 135 includes at least a portion of suspend agent 134 and is configured to perform the functionality described herein. In some embodiment, suspend agent 134 is implemented on memory device 130 using firmware, hardware components, or a combination of the above. In one embodiment, suspend agent 134 receives, from a requestor, such as suspend manager 114, a request to suspend performance of an ongoing memory access operation having a long operation time (e.g., a MLC program operation). In response, the suspend agent 134 can cause memory device 130 to enter a suspend state, where the first memory access operation is suspended during the suspend state. Suspend agent can further receive one or more requests to perform additional memory access operations, such as a dynamic SLC program operation, while the memory device 130 is in the suspend state. Suspend agent 134 can initiate the dynamic SLC program operation can notify suspend manager 114 when the dynamic SLC program operation is complete, and the suspend manager 114 can send a request to resume the suspended memory access operation. Further details with regards to the operations of suspend agent 134 are described below.

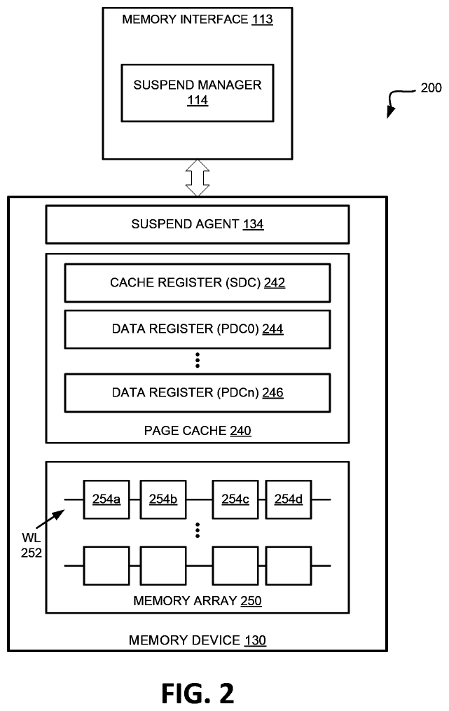

FIG. 2 is a block diagram 200 illustrating a memory sub-system implementing program operation execution during program operation suspend in accordance with some embodiments of the present disclosure. In one embodiment, memory interface 113 is operatively coupled with memory device 130. In one embodiment, memory device 130 includes a page cache 240 and a memory array 250. Memory array 250 can include an array of memory cells formed at the intersections of wordlines, such as wordline 252, and bitlines (not shown). In one embodiment, the memory cells are grouped in to blocks, which can be further divided into sub-blocks, where a given wordline, such as wordline 252, is shared across a number of sub-blocks 254a, 254b, 254c, 254d, for example. In one embodiment, each sub-block corresponds to a separate plane in the memory array 250. The group of memory cells associated with a wordline within a sub-block is referred to as a physical page. Each physical page in one of the sub-blocks can include multiple page types. For example, a physical page formed from single level cells (SLCs) has a single page type referred to as a lower logical page (LP). Multi-level cell (MLC) physical page types can include LPs and upper logical pages (UPs), TLC physical page types are LPs, UPs, and extra logical pages (XPs), and QLC physical page types are LPs, UPs, XPs and top logical pages (TPs). For example, a physical page formed from memory cells of the QLC memory type can have a total of four logical pages, where each logical page can store data distinct from the data stored in the other logical pages associated with that physical page.

Depending on the programming scheme used, each logical page of a memory cell can be programmed in a separate programming pass, or multiple logical pages can be programmed together. For example, in a QLC physical page, the LP can be programmed on one pass, and the UP, XP and TP can be programmed on a second pass. Other programming schemes are possible. In this example, however, prior to programming the UP, XP, and TP in the second pass, the data from the LP is first read from the physical page in memory array 250 and can be stored in the page cache 240 of memory device 130. The page cache 240 is a buffer used to temporarily store data being read from or written to memory array 250 of memory device 130, and can include a cache register 242 and one or more data registers 244-246. For a read operation, the data is read from memory array 250 into one of data registers 244-246, and then into cache register 242. Memory interface 113 can then read out the data from cache register 242. For a program operation, memory interface 113 writes the data to cache register 242, which is then passed to one of data registers 244-246, and finally programmed to memory array 250. If the program operation includes multiple pages (e.g., UP, XP, and TP), each page can have a dedicated data register to hold the corresponding page data.

In one embodiment, suspend manager 114 can send a request to suspend a memory access operation (e.g., a suspend command) to memory device 130 while the memory access operation is currently being performed. The suspend command can be received by suspend agent 134, which can cause memory device 130 to enter a suspend state. In the suspend state, the ongoing memory access operation being performed on memory array 250 (e.g., on wordline 252 of memory array 250) is suspended. In one embodiment, suspend agent 134 stores progress information associated with the suspended memory access operation in page cache 240. For example, suspend agent 134 can store data already programmed to memory array 250 in page cache 240 (e.g., in one of data registers 244-246) responsive to receiving the suspend command, where such data can be used to resume the suspended memory access operation at a later time.

Once the memory access operation is suspended, suspend manager 114 can send a request to perform another memory access operation, such as a dynamic SLC program operation on the memory array 250, while memory device 130 is in the suspend state. Suspend agent 134 can receive the request and initiate the dynamic SLC program operation on memory array 250. In one embodiment, two or more memory access operations can be performed while the original memory access operation is suspended. Upon completion of the dynamic SLC program operation (and any other operations), suspend agent 134 can provide a notification to the requestor indicating that the dynamic SLC program operation is complete. For example, suspend agent 134 can set a ready/busy signal to a certain level (e.g., a high voltage representing a logic “1”) to indicate that the memory device 130 is ready to receive subsequent commands. In response, suspend manager can send a request (e.g., a resume command) to resume the previously suspended memory access operation to memory device 130. Suspend agent 134 can receive the request, cause the memory device 130 to exit the suspend state, and resume the original memory access operation on memory array 250 using the progress information from page cache 240. For example, suspend agent 134 can read the data stored in page cache 240, which was previously written to memory array 250, and compare that data to the data in the resume command to determine where the memory access operation left off when suspended. Suspend agent 134 can thus resume programming the data for the memory access operation to memory array 250 from that point.

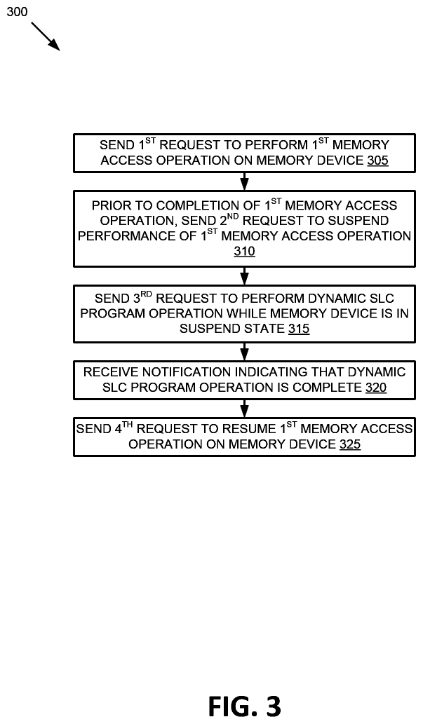

FIG. 3 is a flow diagram of an example controller method of program operation execution during program operation suspend in accordance with some embodiments of the present disclosure. The method 300 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 300 is performed by suspend manager 114 of FIG. 1 and FIG. 2. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At operation 305, a command/request is sent. For example, processing logic (e.g., suspend manager 114) can send, to a memory device, such as memory device 130, a first request to perform a first memory access operation on a memory array of the memory device, such as memory array 250. In one embodiment, the first memory access operation comprises at least one of a program operation, a read operation, or an erase operation. For example, the first memory access operation can include a MLC program operation, such as a TLC program operation or a QLC program operation. In one embodiment, suspend manager 114 sends a request to perform the first memory access operation, such as a first memory access command, to memory device 130, which is received by suspend agent 134. In one embodiment, suspend manager 114 sends the request in response to a request received from some other component, such as host system 120.

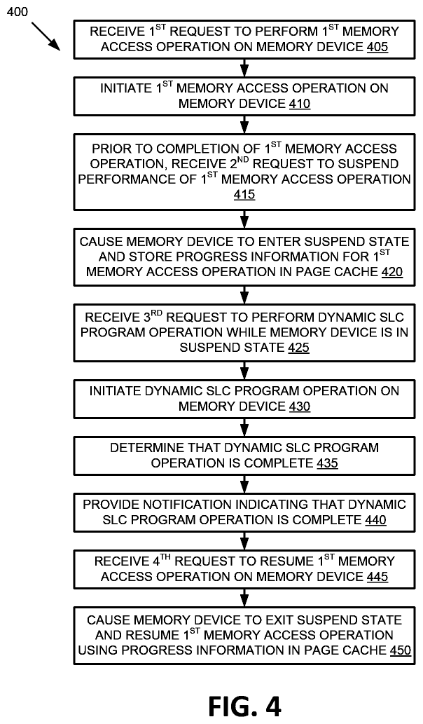

At operation 310, a command/request is sent. For example, prior to completion of the first memory access operation (i.e., while the memory device 130 is still performing the first memory access operation), the processing logic can send, to the memory device 130, a second request to suspend performance of the first memory access operation. In one embodiment, suspend manager 114 sends a request to suspend the first memory access operation, such as a suspend command, to memory device 130, which is received by suspend agent 134. In response, suspend agent 134 can cause memory device 130 to enter a suspend state, where the first memory access operation is suspended during the suspend state, as described in more detail with respect to FIG. 4.

At operation 315, a command/request is sent. For example, the processing logic can send, to the memory device 130, a third request to perform a second memory access operation on the memory array 250 of memory device 130. In one embodiment, the second memory access operation comprises at least one of a program operation, a read operation, or an erase operation. For example, the second memory access operation can include a dynamic SLC program operation. The dynamic SLC program operation can have a lower program time than the MLC program operation and a lower program time than a static SLC program operation. That is, the dynamic SLC program operation can be complete faster than those other operations. In addition, the dynamic SLC program operation is performed using different trim settings for the memory device than those used for the MLC program operation or a static SLC program operation. Furthermore, the dynamic SLC program operation is performed with respect to data having a lower priority level than data associated with the MLC program operation or a static SLC program operation. For example, when more critical data (i.e., data having a higher priority level) is to be written to memory device 130, suspend manager 114 can issue a static SLC program operation. When less critical data is to be written to memory device 130, however, suspend manager 114 can issue a dynamic SLC program operation. In one embodiment, suspend manager 114 sends a request to perform the second memory access operation, such as a second memory access command, to memory device 130, which is received by suspend agent 134 while the memory device 130 is in the suspend state. In other embodiments, two or more additional memory access operations can be performed while the memory device 130 is in the suspend state.

At operation 320, a notification is received. For example, the processing logic can receive, from memory device 130, a notification indicating that the second memory access operation (e.g., the dynamic SLC program operation) is complete. In one embodiment, memory device 130 outputs a ready/busy signal indicative of the status of memory device 130. For example, the signal can have a first voltage level (e.g., a high voltage level indicating a logic “1”) when the memory device 130 is ready (i.e., not currently performing a memory access operation) and a second voltage level (e.g., a low voltage level indicating a logic “0” when the memory device 130 is busy (i.e., currently performing a memory access operation). In one embodiment, upon completion of the second memory access operation, suspend agent 134 can set the value of the ready/busy signal to the corresponding level, which is received by suspend manager 114. Suspend manager 114 can decode the signal level to determine the state of memory device 130.

At operation 325, a command/request is sent. For example, the processing logic can send, to the memory device 130, a fourth request to resume the first memory access operation (e.g., the previously suspended MLC program operation) on the memory array 250 of memory device 130. In one embodiment, suspend manager 114 sends a request to resume the first memory access operation, such as a resume command, to memory device 130, which is received by suspend agent 134. In one embodiment, the resume command causes suspend manager to resume the first memory access operation at a point where the first memory access operation left off, as described in more detail with respect to FIG. 4.

FIG. 4 is a flow diagram of an example memory device method of program operation execution during program operation suspend in accordance with some embodiments of the present disclosure. The method 400 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 400 is performed by suspend agent 134 of FIG. 1 and FIG. 2. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At operation 405, a command/request is received. For example, processing logic (e.g., suspend agent 134) can receive, from a requestor, such as memory sub-system controller 115, a first request to perform a first memory access operation on a memory array, such as memory array 250, of a memory device, such as memory device 130. In one embodiment, the first memory access operation comprises at least one of a program operation, a read operation, or an erase operation. For example, the first memory access operation can include a MLC program operation, such as a TLC program operation or a QLC program operation. In one embodiment, suspend manager 114 sends a request to perform the first memory access operation, such as a first memory access command, to memory device 130, which is received by suspend agent 134.

At operation 410, a memory access operation is initiated. For example, the processing logic can initiate the first memory access operation on the memory array 250. In one embodiment, suspend agent 134 can apply one or more programming pulses to the corresponding wordlines, such as wordline 252, of memory array 250 to store the data associated with the first memory access operation in the memory cells of the memory array 250. Since the first memory access operation can include a MLC program operation, multiple pages can be programmed in one or more programming passes, such as a LP, UP, XP, and TP.

At operation 415, a command/request is received. For example, prior to completion of the first memory access operation (i.e., while the memory device 130 is still performing the first memory access operation), the processing logic can receive, from the requestor, a second request to suspend performance of the first memory access operation. In one embodiment, suspend manager 114 sends a request to suspend the first memory access operation, such as a suspend command, to memory device 130, which is received by suspend agent 134.

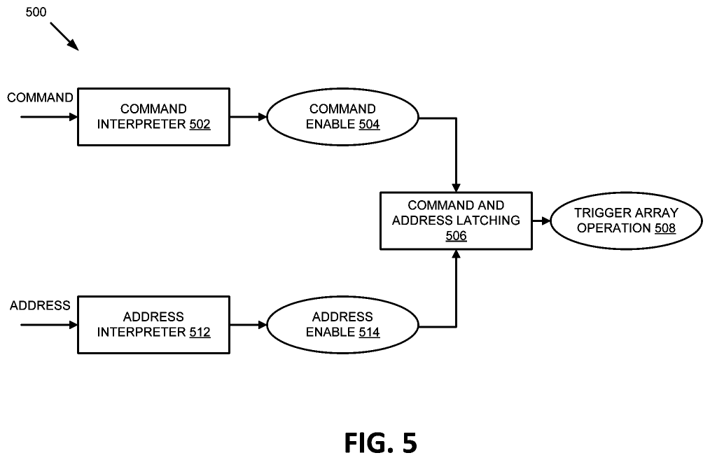

At operation 420, a state of the memory device is changed. For example, in response to receiving the suspend command, suspend agent 134 can cause memory device 130 to enter a suspend state. In one embodiment, the first memory access operation is suspended (i.e., paused, stopped, halted) during the suspend state. In one embodiment, suspend agent 134 stores progress information associated with the first memory access operation in a page cache, such as page cache 240, of memory device 130. For example, suspend agent 134 can store data already programmed to memory array 250 in page cache 240 (e.g., in one of data registers 244-246) responsive to entering the suspend state, where such data can be used to resume the suspended memory access operation at a later time. In one embodiment, suspend agent 134 implements a command state machine, the operation 500 of which is illustrated in FIG. 5. As illustrated, the command state machine includes a command interpreter 502, which receives and identifies commands (e.g., the suspend command) from the requestor. At 504, the command state machine enables the command. For example, if the received command is a suspend command, the command state machine can cause memory device 130 to transition from a current state (e.g., a normal operation state) to the suspend state. In the suspend state, the command state machine can further receive additional commands (e.g., memory access commands) as described below. The command state machine further includes an address interpreter 512 which receives and identifies addresses corresponding to the received commands from the requestor. At 514, the command state machine enables the addresses. The command state machine performs both command and address latching at 506 and triggers an array operation at 508. In one embodiment, the latching is performed using flip-flop circuits or other devices to temporarily store the command and address enable signals before the array operation is performed.

At operation 425, a command/request is received. For example, the processing logic can receive, from the requestor, a third request to perform a second memory access operation on the memory array 250 of memory device 130. In one embodiment, the second memory access operation comprises at least one of a program operation, a read operation, or an erase operation. For example, the second memory access operation can include a dynamic SLC program operation. The dynamic SLC program operation can have a lower program time than the MLC program operation and a lower program time than a static SLC program operation. That is, the dynamic SLC program operation can be complete faster than those other operations. In addition, the dynamic SLC program operation is performed using different trim settings for the memory device than those used for the MLC program operation or a static SLC program operation. Furthermore, the dynamic SLC program operation is performed with respect to data having a lower priority level than data associated with the MLC program operation or a static SLC program operation. For example, when more critical data (i.e., data having a higher priority level) is to be written to memory device 130, suspend manager 114 can issue a static SLC program operation. When less critical data is to be written to memory device 130, however, suspend manager 114 can issue a dynamic SLC program operation. In one embodiment, suspend manager 114 sends a request to perform the second memory access operation, such as a second memory access command, to memory device 130, which is received by suspend agent 134 while the memory device 130 is in the suspend state. In other embodiments, two or more additional memory access operations can be performed while the memory device 130 is in the suspend state.

At operation 430, a memory access operation is initiated. For example, the processing logic can initiate the second memory access operation (e.g., the dynamic SLC program operation) on the memory array 250. In one embodiment, suspend agent 134 can apply one or more programming pulses to the corresponding wordlines, such as wordline 252, of memory array 250 to store the data associated with the second memory access operation in the memory cells of the memory array 250. At operation 435, the processing logic determines that the dynamic SLC program operation is complete. The operation is complete when all of the associated data has been successfully programed to the memory array 250.

At operation 440, a notification is provided. For example, the processing logic can provide, to the requestor, a notification indicating that the second memory access operation (e.g., the dynamic SLC program operation) is complete. In one embodiment, memory device 130 outputs a ready/busy signal indicative of the status of memory device 130. For example, the signal can have a first voltage level (e.g., a high voltage level indicating a logic “1”) when the memory device 130 is ready (i.e., not currently performing a memory access operation) and a second voltage level (e.g., a low voltage level indicating a logic “0” when the memory device 130 is busy (i.e., currently performing a memory access operation). In one embodiment, upon completion of the second memory access operation, suspend agent 134 can set the value of the ready/busy signal to the corresponding level, which is received by suspend manager 114. Suspend manager 114 can decode the signal level to determine the state of memory device 130.

At operation 445, a command/request is received. For example, the processing logic can receive, from the requestor, a fourth request to resume the first memory access operation (e.g., the previously suspended MLC program operation) on the memory array 250 of memory device 130. In one embodiment, suspend manager 114 sends a request to resume the first memory access operation, such as a resume command, to memory device 130, which is received by suspend agent 134.

At operation 450, a memory access operation is resumed. For example, the processing logic can cause memory device 130 to exit the suspend state and resume the first memory access operation at a point where the first memory access operation left off using the progress information from page cache 240. In one embodiment, suspend agent 134 can read the data stored in page cache 240, which was previously written to memory array 250, and compare that data to the data in the resume command to determine where the memory access operation left off when suspended. Suspend agent 134 can thus resume programming the data for the first memory access operation to memory array 250 from that point.

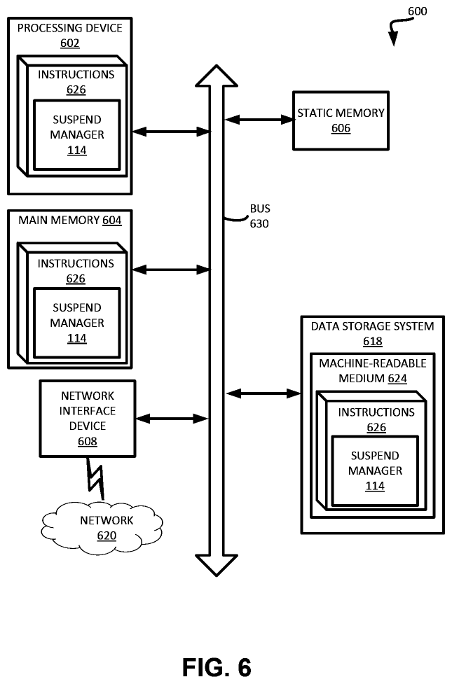

FIG. 6 illustrates an example machine of a computer system 600 within which a set of instructions, for causing the machine to perform any one or more of the methodologies discussed herein, can be executed. In some embodiments, the computer system 600 can correspond to a host system (e.g., the host system 120 of FIG. 1) that includes, is coupled to, or utilizes a memory sub-system (e.g., the memory sub-system 110 of FIG. 1) or can be used to perform the operations of a controller (e.g., to execute an operating system to perform operations corresponding to suspend manager 114 and/or suspend agent 134 of FIG. 1). In alternative embodiments, the machine can be connected (e.g., networked) to other machines in a LAN, an intranet, an extranet, and/or the Internet. The machine can operate in the capacity of a server or a client machine in client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 600 includes a processing device 602, a main memory 604 (e.g., read-only memory (ROM), flash memory, dynamic random access memory (DRAM) such as synchronous DRAM (SDRAM) or Rambus DRAM (RDRAM), etc.), a static memory 606 (e.g., flash memory, static random access memory (SRAM), etc.), and a data storage system 618, which communicate with each other via a bus 630.

Processing device 602 represents one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. Processing device 602 can also be one or more special-purpose processing devices such as an application specific integrated circuit (ASIC), a field programmable gate array (FPGA), a digital signal processor (DSP), network processor, or the like. The processing device 602 is configured to execute instructions 626 for performing the operations and steps discussed herein. The computer system 600 can further include a network interface device 608 to communicate over the network 620.

The data storage system 618 can include a machine-readable storage medium 624 (also known as a computer-readable medium, such as a non-transitory computer-readable medium) on which is stored one or more sets of instructions 626 or software embodying any one or more of the methodologies or functions described herein. The instructions 626 can also reside, completely or at least partially, within the main memory 604 and/or within the processing device 602 during execution thereof by the computer system 600, the main memory 604 and the processing device 602 also constituting machine-readable storage media. The machine-readable storage medium 624, data storage system 618, and/or main memory 604 can correspond to the memory sub-system 110 of FIG. 1.

In one embodiment, the instructions 626 include instructions to implement functionality corresponding to suspend manager 114 and/or suspend agent 134 of FIG. 1). While the machine-readable storage medium 624 is shown in an example embodiment to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general purpose computer selectively activated or reconfigured by a computer program stored in the computer. Such a computer program can be stored in a computer readable storage medium, such as, but not limited to, any type of disk including floppy disks, optical disks, CD-ROMs, and magnetic-optical disks, read-only memories (ROMs), random access memories (RAMs), EPROMs, EEPROMs, magnetic or optical cards, or any type of media suitable for storing electronic instructions, each coupled to a computer system bus.

The algorithms and displays presented herein are not inherently related to any particular computer or other apparatus. Various general purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium having stored thereon instructions, which can be used to program a computer system (or other electronic devices) to perform a process according to the present disclosure. A machine-readable medium includes any mechanism for storing information in a form readable by a machine (e.g., a computer). In some embodiments, a machine-readable (e.g., computer-readable) medium includes a machine (e.g., a computer) readable storage medium such as a read only memory (“ROM”), random access memory (“RAM”), magnetic disk storage media, optical storage media, flash memory components, etc.

In the foregoing specification, embodiments of the disclosure have been described with reference to specific example embodiments thereof. It will be evident that various modifications can be made thereto without departing from the broader spirit and scope of embodiments of the disclosure as set forth in the following claims. The specification and drawings are, accordingly, to be regarded in an illustrative sense rather than a restrictive sense.

What is claimed is:

1. A memory device comprising:
a memory array; and
control logic, operatively coupled with the memory array, to perform operations comprising:
receiving, from a requestor, a first request to perform a first memory access operation on the memory array;
initiating the first memory access operation on the memory array;
prior to completion of the first memory access operation, receiving, from the requestor, a second request to suspend performance of the first memory access operation;
causing the memory device to enter a suspend state, wherein the first memory access operation is suspended during the suspend state;
receiving, from the requestor, a third request to perform a dynamic single-level cell (SLC) program operation on the memory array while the memory device is in the suspend state; and
initiating the dynamic SLC program operation on the memory array.

2. The memory device of claim 1, wherein the requestor comprises a memory sub-system controller of a memory sub-system comprising the memory device.

3. The memory device of claim 1, wherein the first memory access operation comprises a multi-level cell (MLC) program operation.

4. The memory device of claim 3, wherein the dynamic SLC program operation has a lower program time than the MLC program operation.

5. The memory device of claim 3, wherein the dynamic SLC program operation is performed using different trim settings for the memory device and with respect to data having a lower priority level than data associated with the MLC program operation.

6. The memory device of claim 1, further comprising:
a page cache operatively coupled with the memory array and the control logic, wherein while the memory device is in the suspend state, the control logic is to store progress information associated with the first memory access operation in the page cache.

7. The memory device of claim 6, wherein the control logic is to perform operations further comprising:
determining that the dynamic SLC program operation is complete;
providing a notification to the requestor indicating that the dynamic SLC program operation is complete;
receiving, from the requestor, a fourth request to resume the first memory access operation on the memory array;
causing the memory device to exit the suspend state; and
resuming the first memory access operation on the memory array using the progress information from the page cache.

8. A method comprising:
receiving, from a requestor, a first request to perform a first memory access operation on a memory device;
initiating the first memory access operation on the memory device;
prior to completion of the first memory access operation, receiving, from the requestor, a second request to suspend performance of the first memory access operation;
causing the memory device to enter a suspend state, wherein the first memory access operation is suspended during the suspend state;
receiving, from the requestor, a third request to perform a dynamic single-level cell (SLC) program operation on the memory device while the memory device is in the suspend state; and
initiating the dynamic SLC program operation on the memory device.

9. The method of claim 8, wherein the requestor comprises a memory sub-system controller of a memory sub-system comprising the memory device.

10. The method of claim 8, wherein the first memory access operation comprises a multi-level cell (MLC) program operation.

11. The method of claim 10, wherein the dynamic SLC program operation has a lower program time than the MLC program operation.

12. The method of claim 10, wherein the dynamic SLC program operation is performed using different trim settings for the memory device and with respect to data having a lower priority level than data associated with the MLC program operation.

13. The method of claim 8, further comprising:
while the memory device is in the suspend state, storing progress information associated with the first memory access operation in a page cache of the memory device.

14. The method of claim 13, further comprising:
determining that the dynamic SLC program operation is complete;
providing a notification to the requestor indicating that the dynamic SLC program operation is complete;
receiving, from the requestor, a fourth request to resume the first memory access operation on the memory device;
causing the memory device to exit the suspend state; and
resuming the first memory access operation on the memory device using the progress information from the page cache.

15. A method comprising:
sending, to a memory device comprising control logic and a memory array, a first request to perform a first memory access operation on the memory array;
prior to completion of the first memory access operation receiving, sending, to the memory device, a second request to suspend performance of the first memory access operation, the second request to cause the memory device to enter a suspend state, wherein the first memory access operation is suspended during the suspend state; and
sending to the memory device, a third request to perform a dynamic single-level cell (SLC) program operation on the memory device while the memory device is in the suspend state.

16. The method of claim 15, wherein the first memory access operation comprises a multi-level cell (MLC) program operation.

17. The method of claim 16, wherein the dynamic SLC program operation has a lower program time than the MLC program operation.

18. The method of claim 16, wherein the dynamic SLC program operation is performed using different trim settings for the memory device and with respect to data having a lower priority level than data associated with the MLC program operation.

19. The method of claim 15, where the request to suspend performance of the first memory access operation to cause the memory device to store progress information associated with the first memory access operation in a page cache of the memory device.

20. The method of claim 19, further comprising:
receiving, from the memory device, a notification indicating that the dynamic SLC program operation is complete;
sending, to the memory device, a fourth request to resume the first memory access operation on the memory device, the fourth request to cause the memory device to exit the suspend state and resume the first memory access operation on the memory device using the progress information from the page cache.
